(19) United States
(12) Patent Application Publication
(10) Pub. No.: US 2013/0151178 A1
(43) Pub. Date: Jun. 13, 2013

(54) Apparatus and Method for Measuring Electric Power

(71) Applicant: Myung Soo Jun, Seoul (KR)

(72) Inventor: Myung Soo Jun, Seoul (KR)

(73) Assignee: HANBIT POWER TECH CO., LTD, Seoul (KR)

(21) Appl. No.: 13/816,176

(22) PCT Filed: Aug. 11, 2010
(86) PCT No.: PCT/KR2010/005253

§ 371 Date: Feb. 8, 2013

(51) Int. Cl. G01R 21/133; G06F 17/00

(52) U.S. Cl. CPC G01R 21/133; G06F 17/00
USPC 702/61

(57) ABSTRACT

Provided are an apparatus and method for accurately measuring electric power when a consumer receives electric power from an electric utility and supplies surplus electric power to the electric utility in power transmission/reception facilities connected in a Y-delta configuration. The apparatus includes a first power meter measuring an amount of electric power at a Y connection side, a second power meter measuring an amount of electric power caused by neutral circulating current at the Y connection side, and an operational unit subtracting a measured value of the second power meter from a measured value of the first power meter, and deciding an amount of actually consumed electric power. The second power meter includes at least one current transformer (CT) and a plurality of potential transformers (PTs). The at least one current transformer detects neutral circulating current (Iₙ) of a neutral ground conductor at the Y connection side.

### BACKGROUND

1. Field of the Invention

The present invention relates to an apparatus and method for measuring electric power, and more particularly, to an apparatus and method for accurately measuring an amount of electric power when a consumer receives electric power from an electric utility and supplies surplus electric power to the electric utility in power transmission/reception facilities connected in a Y-delta configuration.

2. Discussion of Related Art

In general, high-capacity consumers using extra-high voltage of 154 kV or more are directly and individually supplied with electric power produced by an electric utility via a primary substation, and are for the most part equipped with independent power facilities to cope with a variation in load power and secure reserve power. Due to characteristics of this power system, the electric power is supplied from the electric utility to the consumers or is exchanged between the consumers and the electric utility. As such, a charging system for power transmission/reception is operated for each consumer by a mutual contract.

Thus, it is very important to measure electric power transmitted/received between the consumer and the electric utility. Power charges based on power trading also have a considerable influence on operations of the consumer and the electric utility. For this reason, it is common to measure the electric power transmitted/received between the consumer and the electric utility by mutual agreement. A method of measuring the transmitted/received power is based on Blondel's theorem. According to the theorem, when power is supplied to a load by N conductors in multiphase alternate current, an arbitrary one of the N conductors is treated as a common return. When N−1 wattmeters are installed between the common return and the other N−1 conductors, the algebraic sum of the power measured by N−1 wattmeters is equal to the power supplied to the load. In consideration of the theorem, it is preferable to measure the load power using a suitable method according to the characteristics of a power reception system. In the case of the consumer transmitting/receiving the electric power at extra-high voltage of 154 kV, in spite of a difference between grounded systems such as a ungrounded system, a grounded neutral system, etc., due to a load connection (Y-delta connection) of a receiving end, the imbalance of a load, and a periodic wave having the same period despite a non-sinusoidal voltage current waveform, the electric power is typically measured by a 2-element wattmeter (2CT-2PT wattmeter) or a 3-element wattmeter (3CT-3PT wattmeter), and accounting of the power charges is performed.

In power transmission/reception facilities such as a transformer based on a Y-delta connection as in FIG. 4, since a power system of a Y connection side is asymmetrical, zero-sequence voltage occurs at a neutral point, and zero-sequence current circulates through the earth as a return path. Further, neutral current Iₙ can circulate through the interior of a corresponding delta connection to flow to the ground through the neutral point. This neutral current Iₙ exists irrespective of load currents Iₐ₁, I_{b1} and I_{c1} of the delta connection side. When there is no load, i.e., when Iₐ₁+I_{b1}+I_{c1}=0, an amount of electric power of the Y connection side is measured according to the intensity of the neutral current.

Thus, there is a problem in that the charge accounting is performed by the sum of actually consumed electric power of the load side and unnecessary power caused by the neutral current.

Further, even when power is produced by a generator 10 installed on the delta connection side and then is transmitted to the Y connection side, unnecessary power is generated by the neutral current. Thus, there is a problem in that the unnecessary power is included to perform the accounting of the power charges.

### SUMMARY OF THE INVENTION

The present invention is directed to providing an apparatus and method for measuring electric power, capable of measuring only the electric power actually supplied to a load.

One aspect of the present invention provides a method of measuring electric power in power transmission/reception facilities connected in a Y-delta configuration includes: a first process of deciding an amount of electric power at a Y connection side; a second process of deciding an amount of electric power caused by neutral circulating current at the Y connection side; and a third process of subtracting the amount of electric power caused by the neutral circulating current decided in the second process from the amount of electric power decided in the first process, and deciding an amount of actually consumed electric power.

Here, the amount of electric power decided in the first process may be the sum of amounts of electric power of respective phases of the Y connection side.

Further, the amount (P₁) of electric power decided in the first process may be obtained according to the following equation:

P₁=|Iₐ∥Vₐ| cos θₐ+|I_{b}∥V_{b}| cos θ_{b}+|I_{c}∥V_{c}| cos θ_{c}

where P₁ is the amount of electric power of the Y connection side, Iₐ, I_{b}, and I_{c} are phase currents of the Y connection, Vₐ, V_{b}, and V_{c} are phase voltages of the Y connection, and θₐ, θ_{b}, and θ_{c} are phase differences between the phase voltages and currents of the Y connection.

Further, the amount (P₀) of electric power caused by the neutral circulating current decided in the second process may be obtained according to the following equation:

P₀=⅓(|Iₐ+I_{b}+I_{c}|)(|Vₐ| cos θₐₙ+|V_{b}| cos θ_{bn}+|V_{c}| cos θ_{cn})

where P₀ is the amount of electric power caused by the neutral circulating current, Iₐ, I_{b}, and I_{c} are phase currents of the Y connection, Vₐ, V_{b}, and V_{c} are phase voltages of the Y connection, and θₐₙ, θ_{bn}, and θ_{cn} are phase differences between the phase voltages and the neutral circulating current of the Y connection.

In addition, the amount (P_{w}) of actually consumed electric power decided in the third process may be obtained according to the following equation:

P_{w}=P₁−P₀=|Iₐ∥Vₐ| cos θₐ+|I_{b}∥V_{b}| cos θ_{b}+|I_{c}∥V_{c}| cos θ_{c}−[⅓(|Iₐ+I_{b}+I_{c}|)(|Vₐ| cos θₐₙ+|V_{b}| cos θ_{bn}+|V_{c}| cos θ_{cn})]

where P_{w} is the amount of actually consumed electric power, P₁ is the amount of electric power of the Y connection side, P₀ is the amount of electric power caused by the neutral circulating current, Iₐ, I_{b}, and I_{c} are phase currents of the Y connection, Vₐ, V_{b}, and V_{c} are phase voltages of the Y connection, θₐ, θ_{b}, and θ_{c} are phase differences between the phase voltages and currents of the Y connection, and θₐₙ, θ_{bn}, and θ_{cn} are phase differences between the phase voltages and the neutral circulating current of the Y connection.

Another aspect of the present invention provides an apparatus for measuring electric power in power transmission/reception facilities connected in a Y-delta configuration includes: a first power meter measuring an amount of electric power at a Y connection side; a second power meter measuring an amount of electric power caused by neutral circulating current at the Y connection side; and an operational unit subtracting a measured value of the second power meter from a measured value of the first power meter, and deciding an amount of actually consumed electric power.

Here, the second power meter may include at least one current transformer (CT) and a plurality of potential transformers (PTs), and the at least one current transformer may detect neutral circulating current (Iₙ) of a neutral ground conductor at the Y connection side.

Further, the plurality of potential transformers (PTs) may measure respective phase voltages of a Y connection.

Further, the first power meter may decide the measured value (P₁) from the following equation:

P₁=|Iₐ∥Vₐ| cos θₐ+|I_{b}∥V_{b}| cos θ_{b}+|I_{c}∥V_{c}| cos θ_{c}

where P₁ is the amount of electric power of the Y connection side, Iₐ, I_{b}, and I_{c} are phase currents of the Y connection, Vₐ, V_{b}, and V_{c} are phase voltages of the Y connection, and θₐ, θ_{b}, and θ_{c} are phase differences between the phase voltages and currents of the Y connection.

Further, the second power meter may decide the measured value (P₀) from the following equation:

P₀=⅓|Iₙ|(|Vₐ| cos θₐₙ+|V_{b}| cos θ_{bn}+|V_{c}| cos θ_{cn})

where P₀ is the amount of electric power caused by the neutral circulating current, Iₙ is the neutral circulating current of the Y connection, Vₐ, V_{b}, and V_{c} are phase voltages of the Y connection, and θₐₙ, θ_{bn}, and θ_{cn} are phase differences between the phase voltages and the neutral circulating current of the Y connection.

Further, the operational unit may decide the amount (P_{w}) of actually consumed electric power from the following equation:

P_{w}=P₁−P₀=|Iₐ∥Vₐ| cos θₐ+|I_{b}∥V_{b}| cos θ_{b}+|I_{c}∥V_{c}| cos θ_{c}−[ 1/3|Iₙ|(|Vₐ| cos θₐₙ+|V_{b}| cos θ_{bn}+|V_{c}| cos θ_{cn})]

where P_{w} is the amount of actually consumed electric power, P₁ is the amount of electric power of the Y connection side, P₀ is the amount of electric power caused by the neutral circulating current, Iₐ, I_{b}, and I_{c} are phase currents of the Y connection, Iₙ is the neutral circulating current of the Y connection, Vₐ, V_{b}, and V_{c} are phase voltages of the Y connection, θₐ, θ_{b}, and θ_{c} are phase differences between the phase voltages and currents of the Y connection, and θₐₙ, θ_{bn}, and θ_{cn} are phase differences between the phase voltages and the neutral circulating current of the Y connection.

According to the apparatus and method for measuring electric power as described above, errors caused by the neutral circulating current are removed. Thereby, hyper- or hypo-measurement of received or transmitted power can be prevented to enable fair trading. Particularly, a consumer and an electric utility can claim accurate power rates in connection with the measurement of amounts of received and transmitted power, and thus the transparency of trading is increased.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a view for describing a method of measuring electric power in accordance with a first embodiment of the present invention;

FIG. 2 is a block diagram of an apparatus for measuring electric power in accordance with a second embodiment of the present invention;

FIG. 3 is a detailed view of the apparatus for measuring electric power shown in FIG. 2; and

FIG. 4 is a schematic view of a transformer having a typical Y-delta connection configuration.

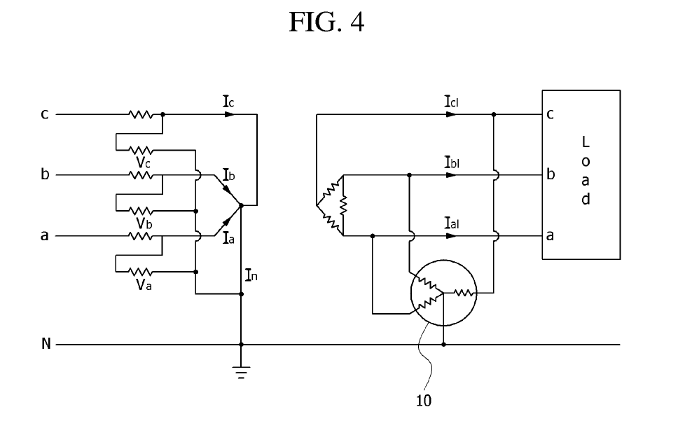

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. The following embodiments are described in order to enable those of ordinary skill in the art to embody and practice the present invention.

Although the terms first, second, etc. may be used to describe various elements, these elements are not limited by these terms. These terms are only used to distinguish one element from another. For example, a first element could be termed a second element, and, similarly, a second element could be termed a first element, without departing from the scope of exemplary embodiments. The term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of exemplary embodiments. The singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, components and/or groups thereof, but do not preclude the presence or addition of one or more other features, integers, steps, operations, elements, components and/or groups thereof.

With reference to the appended drawings, exemplary embodiments of the present invention will be described in detail below. To aid in understanding the present invention, like numbers refer to like elements throughout the description of the figures, and the description of the same elements will be not reiterated.

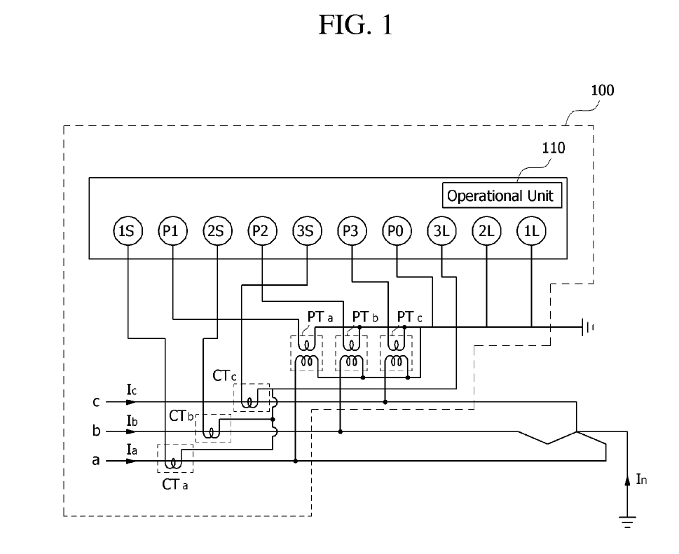

FIG. 1 is a view for describing a method of measuring electric power using an operational unit in accordance with a first embodiment of the present invention, and schematically shows a 3-element wattmeter.

An apparatus 100 for measuring electric power (hereinafter referred to as a “wattmeter 100”) of FIG. 1 includes potential transformers PTₐ, PT_{b}, and PT_{c} for measuring respective phase voltages of a Y connection, current transformers CTₐ, CT_{b}, and CT_{c} for measuring the respective phase currents of the Y connection, a plurality of connection terminals 1S, P1, 2S, P2, 3S, P3, P0, 3L, 2L, and 1L, and an operational unit 110 receiving outputs of the potential transformers PTₐ, PT_{b}, and PT_{c} and the current transformers CTₐ, CT_{b}, and CT_{c} to decide a real amount of electric power. The decision of the operational unit 110 refers to measurement or calculation.

The operational unit 110 decides the amount of actually consumed electric power by subtracting an amount of electric power caused by neutral circulating current from the sum of respective amounts of phase electric power of the Y connection. This series of processes is previously converted into logic algorithms, stored in the operational unit 110, and calculated and decided by an integrated circuit (IC) chip or a micro computer (not shown).

The sum P₁ of amounts of electric power of respective phases of the Y connection is decided according to Equation 1 below.

P₁=|Iₐ∥Vₐ| cos θₐ+|I_{b}∥V_{b}| cos θ_{b}+|I_{c}∥V_{c}| cos θ_{c} Equation 1
where P₁ is the amount of electric power of the Y connection side, Iₐ, I_{b}, and I_{c} are the phase currents of the Y connection, Vₐ, V_{b}, and V_{c} are the phase voltages of the Y connection, and θₐ, θ_{b}, and θ_{c} are the phase differences between the phase voltages and currents of the Y connection.

Each of the voltages and currents is expressed by a phase vector.

Further, the amount P₀ of electric power caused by the neutral circulating current is decided according to Equation 2 below.

P₀=⅓(|Iₐ+I_{b}+I_{c}|)(|Vₐ| cos θₐₙ+|V_{b}| cos θ_{bn}+|V_{c}| cos θ_{cn}) Equation 2
where P₀ is the amount of electric power caused by the neutral circulating current, Iₐ, I_{b}, and I_{c} are the phase currents of the Y connection, Vₐ, V_{b}, and V_{c} are the phase voltages of the Y connection, and θₐₙ, θ_{bn}, and θ_{cn} are the phase differences between the phase voltages and the neutral circulating current of the Y connection.

Phase currents circulating through a delta connection side are in phase. Thus, the neutral circulating current Iₙ is uniformly distributed to the phases of the Y connection side, and ⅓Iₙ flows to each phase of the Y connection side. Thus, the amount of electric power caused by the neutral circulating current is P₀=⅓(|Iₐ+I_{b}+I_{c}|)(|Vₐ| cos θₐₙ+|V_{b}| cos θ_{bn}+|V_{c}| cos θ_{cn}). The sum of currents entering or leaving a neutral point on the basis of a direction of the current of FIG. 1 is Iₐ+I_{b}+Iₙ+Iₙ=0 according to Kirchoff's laws. Thus, the neutral circulating current is expressed by Iₙ=−(Iₐ+I_{b}+I_{c}). When this is substituted into the above equation, the result is arranged like Equation 2.

Thus, for the amount of actually consumed electric power, the amount P₀ of electric power caused by the neutral circulating current should be subtracted from the sum P₁ of the amounts of electric power of the respective phases, and thus is decided as in Equation 3 below.

P_{w}=P₁−P₀=|Iₐ∥Vₐ| cos θₐ+|I_{b}∥V_{b}| cos θ_{b}+|I_{c}∥V_{c}| cos θ_{c}−[⅓(|Iₐ+I_{b}+I_{c}|)(|Vₐ| cos θₐₙ+|V_{b}| cos θ_{bn}+|V_{c}| cos θ_{cn})] Equation 3
where P_{w} is the amount of actually consumed electric power, P₁ is the amount of electric power of the Y connection side, P₀ is the amount of electric power caused by the neutral circulating current, Iₐ, I_{b}, and I_{c} are the phase currents of the Y connection, Vₐ, V_{b}, and V_{c} are the phase voltages of the Y connection, θₐ, θ_{b}, and θ_{c} are the phase differences between the phase voltages and currents of the Y connection, and θₐₙ, θ_{bn}, and θ_{cn} are the phase differences between the phase voltages and the neutral circulating current of the Y connection.

Equations 1 to 3 are converted into logic algorithms, and are recorded in the operational unit 110. When measured values of the current transformers and the potential transformers are substituted and calculated, the amount of actually consumed electric power from which the amount of electric power caused by the neutral circulating current is subtracted can be easily measured.

In the present embodiment, the high-voltage power transmission/reception line having the current transformers and the potential transformers has been described as an example. However, the present embodiment is not limited to this example. For example, a typical wattmeter includes functions of the current transformer and the potential transformer. Due to the limitation of capacity, the current transformers and the potential transformers are separately installed, and the amount of electric power of the high-voltage power transmission/reception line is measured. Accordingly, in a low-voltage power transmission/reception line, the operation of the aforementioned embodiment can be sufficiently performed only by the wattmeter having the operational unit 110 in which Equations 1 to 3 are converted into logic algorithms.

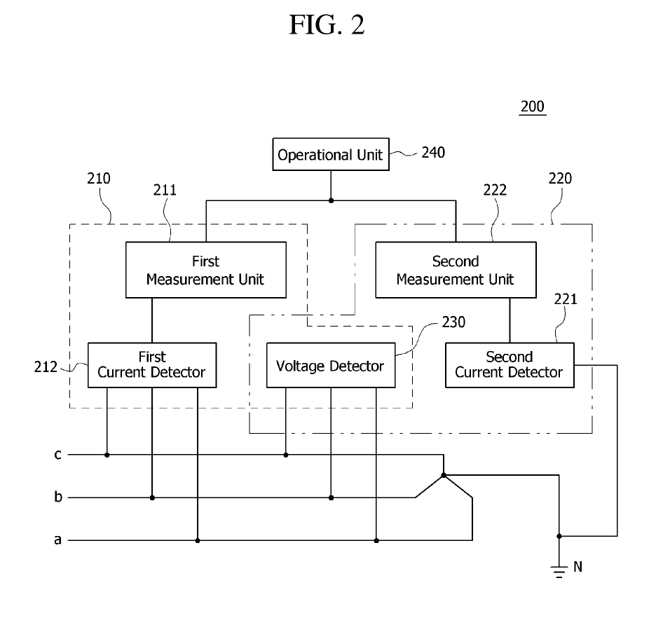

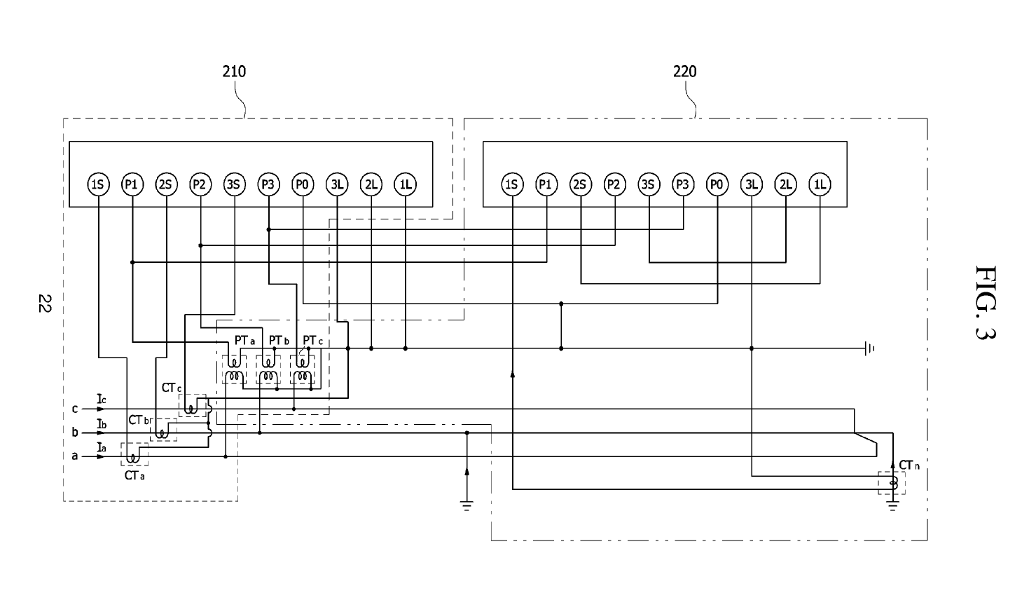

FIG. 2 is a block diagram of a wattmeter according to a second embodiment of the present invention, and FIG. 3 is a detailed circuit diagram of FIG. 2. A configuration of the wattmeter will be described in detail below.

A wattmeter 200 of the present embodiment includes a first power meter 210 for measuring an amount of electric power of a Y connection side, a second power meter 220 for measuring an amount of electric power caused by neutral circulating current at the Y connection side, and an operational unit 240 for receiving measured values of the first and second power meters 210 and 220 and calculating the received values to decide an amount of actually consumed electric power excluding the amount of electric power caused by circulating current. The first power meter 210 includes a first current detector 212 for measuring each phase current of the Y connection side, a voltage detector 230 for measuring each phase voltage, and a first measurement unit 211 receiving values of the first current detector 212 and the voltage detector 230 to calculate the amount of electric power of the Y connection side. The second power meter 220 includes a second current detector 221 for measuring the neutral circulating current of the Y connection side, the voltage detector 230 for measuring each phase voltage, and a second measurement unit 222 for receiving values of the second current detector 221 and the voltage detector 230 to calculate the amount of electric power caused by neutral circulating current. That is, in a 3-element wattmeter (3CT-3PT wattmeter), the current transformer for measuring the neutral circulating current and the second measurement unit 222 are provided, and the voltage detector 230 is used in common.

The operational unit 240 receives the total amount of electric power of respective phases of the Y connection measured by the first measurement unit 211 and the amount of electric power caused by neutral circulating current measured by the second measurement unit 222 to calculate and decide an amount of actually consumed electric power. This series of processes is previously converted into logic algorithms, stored in the operational unit 240, and calculated and decided by an integrated circuit (IC) chip or a micro computer (not shown).

The sum P₁ of amounts of electric power of respective phases of the Y connection measured by the first measurement unit 211 is decided according to Equation 4 below.

P₁=|Iₐ∥Vₐ| cos θₐ+|I_{b}∥V_{b}| cos θ_{b}+|I_{c}∥V_{c}| cos θ_{c} Equation 4
where P₁ is the amount of electric power of the Y connection side, Iₐ, I_{b}, and I_{c} are the phase currents of the Y connection, Vₐ, V_{b}, and V_{c} are the phase voltages of the Y connection, and θₐ, θ_{b}, and θ_{c} are the phase differences between the phase voltages and currents of the Y connection.

The amount P₀ of electric power caused by the neutral circulating current measured by the second measurement unit 222 is decided according to Equation 5 below.

P₀=⅓|Iₙ|(|Vₐ| cos θₐₙ+|V_{b}| cos θ_{bn}+|V_{c}| cos θ_{cn}) Equation 5
where P₀ is the amount of electric power caused by the neutral circulating current, Iₙ is the neutral circulating current of the Y connection, Vₐ, V_{b}, and V_{c} are the phase voltages of the Y connection, and θₐₙ, θ_{bn}, and θ_{cn} are the phase differences between the phase voltages and the neutral circulating current of the Y connection.

Phase currents circulating through a delta connection side are in phase. Thus, the neutral circulating current Iₙ is uniformly distributed to the phases of the Y connection side, and ⅓Iₙ flows to each phase of the Y connection side. The current flowing to the neutral point is measured by each of the current transformers CTₐ, CT_{b}, CT_{c}, and CTₙ), and thus is processed into a value of the current flowing in the same direction. Thus, the amount of electric power caused by the neutral circulating current is P₀=⅓(|Iₐ+I_{b}+I_{c}|)(|Vₐ| cos θₐₙ+|V_{b}| cos θ_{bn}+|V_{c}| cos θ_{cn}). The sum of currents entering or leaving the neutral point is Iₐ+I_{b}+I_{c}+Iₙ=0 according to Kirchoff's laws. Thus, the neutral circulating current is expressed by Iₙ=−(Iₐ+I_{b}+I_{c}). When this is substituted into the above equation, the result is arranged like Equation 5.

Thus, for the amount of actually consumed electric power, the amount P₀ of electric power caused by the neutral circulating current should be subtracted from the sum P₁ of the amounts of electric power of the respective phases, and thus is decided as in Equation 6 below.

P_{w}=P₁−P₀=|Iₐ∥Vₐ| cos θₐ+|I_{b}∥V_{b}| cos θ_{b}+|I_{c}∥V_{c}| cos θ_{c}−[⅓(|Iₐ+I_{b}+I_{c}|)(|Vₐ| cos θₐₙ+|V_{b}| cos θ_{bn}+|V_{c}| cos θ_{cn})] Equation 6
where P_{w} is the amount of actually consumed electric power, P₁ is the amount of electric power of the Y connection side, P₀ is the amount of electric power caused by the neutral circulating current, Iₐ, I_{b}, and I_{c} are the phase currents of the Y connection, Iₙ is the neutral circulating current of the Y connection, Vₐ, V_{b}, and V_{c} are the phase voltages of the Y connection, θₐ, θ_{b}, and θ_{c} are the phase differences between the phase voltages and currents of the Y connection, and θₐₙ, θ_{bn}, and θ_{cn} are the phase differences between the phase voltages and the neutral circulating current of the Y connection.

As described above, the neutral circulating current is directly detected, and the amount of electric power caused by the detected neutral circulating current is subtracted to decide the amount of actually consumed electric power. Thereby, the amount of electric power can be accurately measured.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method of measuring electric power in power transmission/reception facilities connected in a Y-delta configuration, comprising:
a first process of deciding an amount of electric power at a Y connection side;
a second process of deciding an amount of electric power caused by neutral circulating current at the Y connection side; and
a third process of subtracting the amount of electric power caused by the neutral circulating current decided in the second process from the amount of electric power decided in the first process, and deciding an amount of actually consumed electric power.

2. The method of claim 1, wherein the amount of electric power decided in the first process is the sum of amounts of electric power of respective phases of the Y connection side.

3. The method of claim 1, wherein the amount (P₁) of electric power decided in the first process is obtained according to the following equation:
P₁=|Iₐ∥Vₐ| cos θₐ+|I_{b}∥V_{b}| cos θ_{b}+|I_{c}∥V_{c}| cos θ_{c}
where P₁ is the amount of electric power of the Y connection side, Iₐ, I_{b}, and I_{c} are phase currents of the Y connection, Vₐ, V_{b}, and V_{c} are phase voltages of the Y connection, and θₐ, θ_{b}, and θ_{c} are phase differences between the phase voltages and currents of the Y connection.

4. The method of claim 1, wherein the amount (P₀) of electric power caused by the neutral circulating current decided in the second process is obtained according to the following equation:
P₀=⅓(|Iₐ+I_{b}+I_{c}|)(|Vₐ| cos θₐₙ+|V_{b}| cos θ_{bn}+|V_{c}| cos θ_{cn})
where P₀ is the amount of electric power caused by the neutral circulating current, Iₐ, I_{b}, and I_{c} are phase currents of the Y connection, Vₐ, V_{b}, and V_{c} are phase voltages of the Y connection, and θₐₙ, θ_{bn}, and θ_{cn} are phase differences between the phase voltages and the neutral circulating current of the Y connection.

5. The method of claim 1, wherein the amount (P_{w}) of actually consumed electric power decided in the third process is obtained according to the following equation:
P_{w}=P₁−P₀=|Iₐ∥Vₐ| cos θₐ+|I_{b}∥V_{b}| cos θ_{b}+|I_{c}∥V_{c}| cos θ_{c}−[⅓(|Iₐ+I_{b}+I_{c}|)(|Vₐ| cos θₐₙ+|V_{b}| cos θ_{bn}+|V_{c}| cos θ_{cn})]
where P_{w} is the amount of actually consumed electric power, P₁ is the amount of electric power of the Y connection side, P₀ is the amount of electric power caused by the neutral circulating current, Iₐ, I_{b}, and I_{c} are phase currents of the Y connection, Vₐ, V_{b}, and V_{c} are phase voltages of the Y connection, θₐ, θ_{b}, and θ_{c} are phase differences between the phase voltages and currents of the Y connection, and θₐₙ, θ_{bn}, and θ_{cn} are phase differences between the phase voltages and the neutral circulating current of the Y connection.

6. An apparatus for measuring electric power in power transmission/reception facilities connected in a Y-delta configuration, comprising:
a first power meter measuring an amount of electric power at a Y connection side;
a second power meter measuring an amount of electric power caused by neutral circulating current at the Y connection side; and
an operational unit subtracting a measured value of the second power meter from a measured value of the first power meter, and deciding an amount of actually consumed electric power.

7. The apparatus of claim 6, wherein:
the second power meter includes at least one current transformer (CT), and a plurality of potential transformers (PTs), and
the at least one current transformer detects neutral circulating current (Iₙ) of a neutral ground conductor at the Y connection side.

8. The apparatus of claim 7, wherein the plurality of potential transformers (PTs) measure respective phase voltages of a Y connection.

9. The apparatus of claim 6, wherein the first power meter decides the measured value (P₁) from the following equation:
P₁=|Iₐ∥Vₐ| cos θₐ+|I_{b}∥V_{b}| cos θ_{b}+|I_{c}∥V_{c}| cos θ_{c}
where P₁ is the amount of electric power of the Y connection side, Iₐ, I_{b}, and I_{c} are phase currents of the Y connection, Vₐ, V_{b}, and V_{c} are phase voltages of the Y connection, and θₐ, θ_{b}, and θ_{c} are phase differences between the phase voltages and currents of the Y connection.

10. The apparatus of claim 6, wherein the second power meter decides the measured value (P₀) from the following equation:
P₀=⅓(|Iₐ+I_{b}+I_{c}|)(|Vₐ| cos θₐₙ+|V_{b}| cos θ_{bn}+|V_{c}| cos θ_{cn})
where P₀ is the amount of electric power caused by the neutral circulating current, Iₙ is the neutral circulating current of the Y connection, Vₐ, V_{b}, and V_{c} are phase voltages of the Y connection, and θₐₙ, θ_{bn}, and θ_{cn} are phase differences between the phase voltages and the neutral circulating current of the Y connection.

11. The apparatus of claim 6, wherein the operational unit decides the amount (P_{w}) of actually consumed electric power from the following equation:
P_{w}=P₁−P₀=|Iₐ∥Vₐ| cos θₐ+|I_{b}∥V_{b}| cos θ_{b}+|I_{c}∥V_{c}| cos θ_{c}−[⅓(|Iₐ+I_{b}+I_{c}|)(|Vₐ| cos θₐₙ+|V_{b}| cos θ_{bn}+|V_{c}| cos θ_{cn})]
where P_{w} is the amount of actually consumed electric power, P₁ is the amount of electric power of the Y connection side, P₀ is the amount of electric power caused by the neutral circulating current, Iₐ, I_{b}, and I_{c} are phase currents of the Y connection, Iₙ is the neutral circulating current of the Y connection, Vₐ, V_{b}, and V_{c} are phase voltages of the Y connection, θₐ, θ_{b}, and θ_{c} are phase differences between the phase voltages and currents of the Y connection, and θₐₙ, θ_{bn}, and θ_{cn} are phase differences between the phase voltages and the neutral circulating current of the Y connection.
